(19) United States
(12) Patent Application Publication
(10) Pub. No.: US 2012/0289056 A1
(43) Pub. Date: Nov. 15, 2012

(54) SELECTIVE SILICON NITRIDE ETCH

(75) Inventors: Eric J. Bergman, Kalispell, MT (US); Jerry Dustin Leonhard, Kalispell, MT (US)

(73) Assignee: APPLIED MATERIALS, INC., Santa Clara, CA (US)

(21) Appl. No.: 13/452,687

(22) Filed: Apr. 20, 2012

Related U.S. Application Data
(60) Provisional application No. 61/477,540, filed on Apr. 20, 2011.

(51) Int. Cl. C09K 13/06; H01L 21/302

(52) U.S. Cl. 438/757; 252/79.2; 252/79.4; 257/E21.214

(57) ABSTRACT

Methods and etchant solutions for etching silicon nitride on a workpiece are provided. One method generally includes exposing the workpiece to a chemistry mixture including phosphoric acid and a diluent, wherein the chemistry mixture has a water content of less than 10% by volume, and heating at least one of the workpiece and the chemistry mixture to a process temperature to etch silicon nitride from the workpiece.

### CROSS-REFERENCE TO RELATED APPLICATION

This application claims the benefit of Provisional Application No. 61/477,540, filed Apr. 20, 2011, the disclosure of which is hereby incorporated by reference herein.

### BACKGROUND

Silicon nitride (referred to as SiN, but usually present as Si₃N₄) films are commonly used in the semiconductor industry as diffusion bathers, mechanical protection layers, electrical insulators, and silicon oxidation masks. Silicon nitride is an effective oxidation mask, because silicon oxide (usually present as silicon dioxide, SiO₂) will not grow underneath a silicon nitride layer due to its low oxygen permeability. The selective etch or removal of silicon nitride with a minimal removal of silicon oxide is a desired result in many CMOS manufacturing processes.

Conventional wet etching techniques for silicon nitride have utilized hot (approximately 145 to 180° C.) phosphoric acid solutions with water, typically 85% phosphoric acid and 15% water (by volume). This heated bath process theoretically achieves silicon nitride etch rates reportedly in the range from 20 to 100 angstroms per minute. However, in practice, silicon nitride etch rates only at the low end of this range are typically achieved, due to etch non-uniformity and the need to provide adequate over-etch to ensure complete removal of the silicon nitride layer. Thus, the removal of a 1500 angstrom thick film of silicon nitride will generally require about 45 to about 90 minutes. The selectivity of silicon nitride removal to silicon oxide removal using this process is generally in the range of 8:1, so the loss of silicon oxide can be significant during the silicon nitride etch.

As semiconductor technology has advanced, finer geometry patterns are being used to enable higher density structures to be fabricated. Such finer geometries have created additional problems with hot phosphoric acid etchants for removing silicon nitrides due to insufficient selectivity with respect to silicon oxides. That is, while the hot phosphoric acid etchants will attack silicon nitride and remove it much more rapidly than silicon oxide, the oxide is still attacked as well.

Thus, where a relatively thick layer of silicon nitride must be stripped away in the presence of an area of exposed oxide or a relatively thin layer of an underlying oxide, the potential for there to be a deleterious loss of silicon oxide is significant. Nonuniform layer thicknesses created during deposition steps require that over-etching must be employed to ensure complete removal of the nitride.

If an underlying silicon oxide layer is thin and the selectivity of the etchant for nitride over oxide is not sufficiently high, and if the etch must stop in the underlying oxide layer, then over-etching of the oxide layer can occur. Additionally, for situations where it is desirable or necessary to maintain as much of the silicon oxide layer as possible, an etchant with a higher selectivity for nitride over oxide than is presently possible with hot phosphoric acid etchants is desirable.

Accordingly, there remains a need in the art for a wet etchant process which effectively and efficiently etches silicon nitride at a high etch rate and with high selectivity with respect to exposed or underlying layers of silicon oxide, particularly in a multilayer semiconductor wafer structure. Accordingly, improved methods and chemistries for etching silicon nitride are needed.

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

In accordance with one embodiment of the present disclosure, a method for etching silicon nitride on a workpiece is provided. The method generally includes exposing the workpiece to a chemistry mixture including phosphoric acid and a diluent, wherein the chemistry mixture has a water content of less than 10% by volume. The method further includes heating at least one of the workpiece and the chemistry mixture to a process temperature to etch silicon nitride from the workpiece.

In accordance with another embodiment of the present disclosure, a method for etching silicon nitride on a workpiece is provided. The method generally includes exposing the workpiece to a chemistry mixture including phosphoric acid and a diluent, wherein the chemistry mixture has a non-aqueous diluent content of greater than 60% by volume, a phosphoric acid content in the range of about 10% to about 30% by volume, and a water content of less than 10% by volume. The method further includes heating at least one of the workpiece and the chemistry mixture to a process temperature to etch silicon nitride from the workpiece.

In accordance with another embodiment of the present disclosure, an etchant solution is provided. The etchant solution generally includes a non-aqueous diluent content of greater than 60% by volume, a phosphoric acid content of less than 30% by volume, and a water content of less than 10%.

### DESCRIPTION OF THE DRAWINGS

The foregoing aspects and many of the attendant advantages of this disclosure will become more readily appreciated as the same become better understood by reference to the following detailed description, when taken in conjunction with the accompanying drawings, wherein:

FIG. 1 is a graphical representation of data for etching silicon nitride, specifically, the data relates to phosphoric acid content in etching chemistry (balance is sulfuric acid and water) and the etch rate of silicon nitride achieved by such chemistry;

FIG. 2 is a graphical representation of data for silicon nitride selectivity (as compared to silicon oxide), specifically, the data relates to sulfuric acid content in etching chemistry (balance is phosphoric acid and water) and the selectivity achieved by such chemistry; and

FIG. 3 is a graphical representation of data comparing PECVD and LPCVD silicon nitride, and thermal oxide etching over a temperature range of 200 to 325° C.

### DETAILED DESCRIPTION

Embodiments of the present disclosure relate to methods and chemistries for processing workpieces, such as semiconductor wafers, devices or processing assemblies for processing workpieces, directed to selectively etching silicon nitride in the presence of silicon oxide. More particularly, embodiments relate to methods and chemistries for effectively and efficiently etching a layer of silicon nitride at an improved etch rate and with improved selectivity with respect to exposed or underlying layers of silicon oxide, for example, in a multilayer semiconductor workpiece structure. In accordance with one embodiment of the present disclosure, a method generally includes exposing the workpiece to a chemistry mixture including phosphoric acid and a diluent, and heating either the workpiece or the chemistry mixture to a process temperature to etch the silicon nitride from the workpiece.

The term workpiece, wafer, or semiconductor wafer means any flat media or article, including semiconductor wafers and other substrates or wafers, glass, mask, and optical or memory media, MEMS substrates, or any other workpiece having micro-electric, micro-mechanical, or microelectro-mechanical devices. It should be appreciated that the descriptive terms “micro-feature workpiece” and “workpiece” as used herein include all structures and layers that have been previously deposited and formed at a given point in the processing, and is not intended to be limiting.

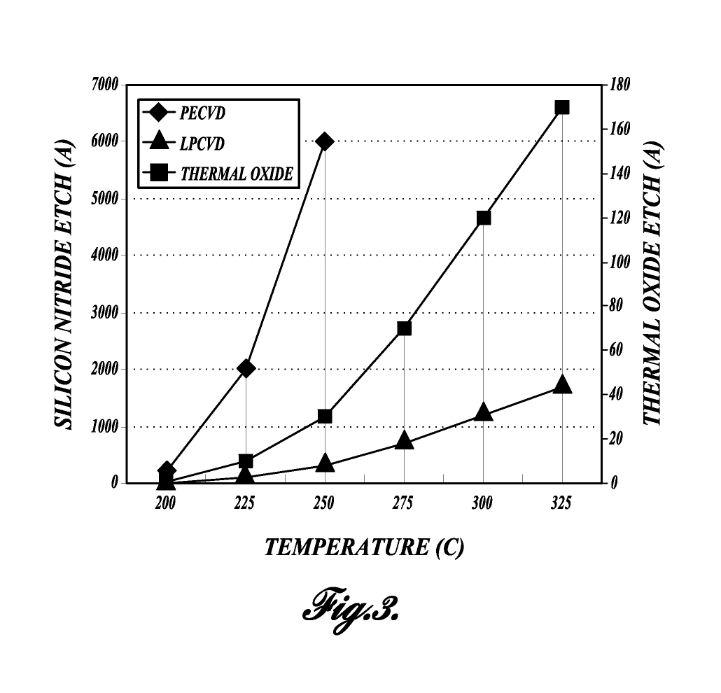

It should further be appreciated that the characteristics of silicon nitride has a significant impact on the etch selectivity achieved. For example, a plasma-enhanced chemical vapor deposition (PECVD) silicon nitride typically etches much faster and more selectively than a low pressure chemical vapor deposition (LPCVD) nitride (see FIG. 3). Therefore, etch rate and selectivity, as described herein, must be considered in view of process conditions and silicon nitride characteristics.

Although conventional wet etching techniques for silicon nitride have utilized hot (approximately 145 to 180° C.) phosphoric acid solutions with water, typically 85% phosphoric acid and 15% water (by volume), the inventors have found success mixing other diluents with the conventional bath. In that regard, the inventors have found that suitable etching is achieved with an etching chemistry that includes phosphoric acid, but also includes other components besides diluting water.

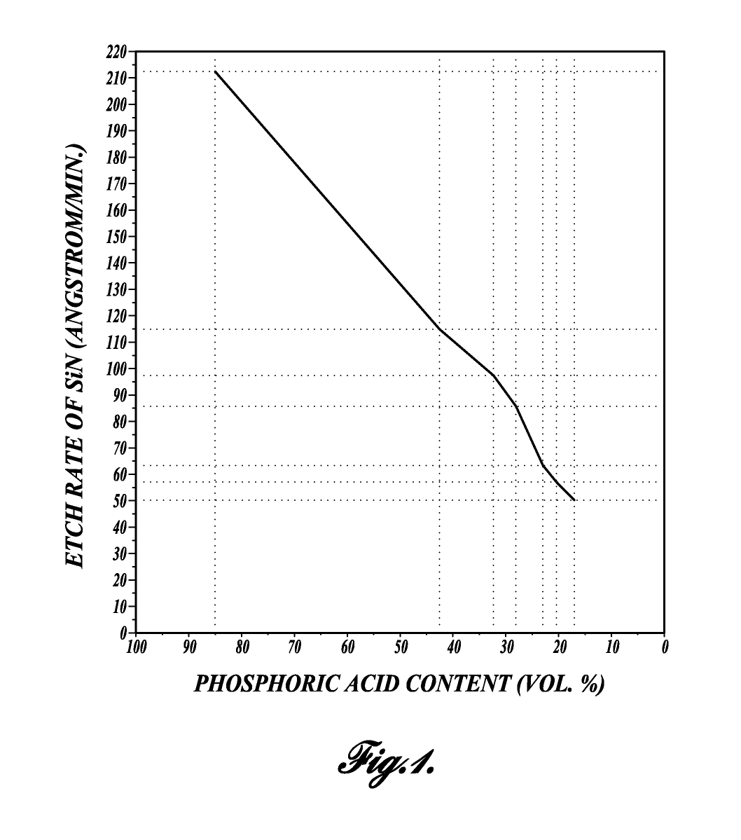

The drawback of a mixed chemistry, however, is a decrease in etch rate. In that regard, FIG. 1 is a graphical representation of data for etching silicon nitride, specifically, the data relates to phosphoric acid content in etching chemistry (balance is sulfuric acid and water) and shows that decreasing phosphoric acid content results in a decreased silicon nitride etch rate achieved by such chemistry.

To account for the decrease in etch rate, new developments in silicon nitride surface heating allow for higher processing temperatures at the etch site in the range of 200 to 350° C. Such higher processing temperatures increase etch rates to even greater rates than those achieved with standard phosphoric acid baths in the range of approximately 145 to 180° C., as described in greater detail below. For example, the data graphically represented in FIG. 3 shows increasing silicon nitride etch rates with increasing temperature in the range of 200 to 325° C.

Embodiments of the present disclosure are therefore directed to a mixed etching chemistry including phosphoric acid and other diluents to achieve desirable selectivity of silicon nitride etch compared to silicon dioxide etch. In one embodiment, the etching chemistry mixture has a phosphoric acid content of less than 30%. In another embodiment, the etching chemistry mixture has a phosphoric acid content in the range of about 10% to about 30%. In another embodiment, the etching chemistry mixture has a phosphoric acid content in the range of about 10% to about 20%.

Suitable diluents that are mixed with phosphoric acid in the etching chemistry may improve the silicon nitride etching chemistry in several different ways. For example, suitable diluents may result in one or more of the following: (1) the diluent may be used to change the water content in the etching chemistry as compared to the water content in the conventional phosphoric acid etching chemistry; (2) the diluent may be used to change the boiling point of the conventional etching chemistry; and (3) the diluent may be used to create a chemical effect that improves the etch achieved by the conventional etching chemistry.

A reduction in water content in etching chemistry increases the boiling point of the etching chemistry and, as a result, may improve the etch rate of silicon nitride. Therefore, a diluent may be used to change the water content in the etching chemistry as compared to the water content in a conventional silicon nitride etching chemistry. For example, the maximum concentration of phosphoric acid that is commercially available is an 85% concentration phosphoric acid solution, having 15% water content (by volume). When mixing a typical 85% concentration phosphoric acid with, for example, a 96% concentration sulfuric acid, having only 4% water content (by volume), the resulting chemistry mixture has a reduced water content that is less than 15%. For example, a 50/50 mixture of 85% concentration phosphoric acid and 96% concentration sulfuric acid has 9.5% water content by volume. Water content in other mixtures of 85% concentration phosphoric acid and 96% concentration sulfuric acid are included below in TABLE 1 of EXAMPLE 1.

In view of the water content in commercially available phosphoric acid, water is generally present in etching chemistry. The effects of the water content in etching chemistry, however, are difficult to quantify. As described in S. Clark, Chemical Etching of Silicon Nitride with Hot Phosphoric Acid (1998-2000), the disclosure of which is hereby expressly incorporated by reference, a more dilute phosphoric acid, when maintained at a constant etch temperature, results in a higher silicon nitride etch rate. However, a more dilute phosphoric acid results in a lower boiling point, resulting in a reduced etch rate.

Further, the inventors, not wishing to be bound by theory, believe that reducing the water content of the etching chemistry, may improve the selectivity of the etching chemistry, as can be see by reviewing the date included below in TABLE 1 of Example 1. For Example, Chemistry 1 having 15 grams of water has a selectivity for silicon nitride over silicon oxide of less than 4:1. In contrast, Chemistry 6 having a 6.2 grams of water has a selectivity for silicon nitride over silicon oxide of greater than 50:1. Notably, sulfuric acid content in Chemistry 1 and Chemistry 6 also vary; therefore, the true effect of variable water content is unclear.

In accordance with one embodiment of the present disclosure, the water content of the chemistry mixture is less than 10%. In accordance with another embodiment, the water content of the chemistry mixture is less than 9.0%. In accordance with another embodiment, the water content of the chemistry mixture is less than 8.0%. In accordance with another embodiment, the water content of the chemistry mixture is less than 7.0%.

In view of the above water and phosphoric acid contents, the balance of the chemistry may be a non-aqueous diluent. In accordance with one embodiment of the present disclosure, the etching chemistry mixture has a non-aqueous diluent content of greater than 60%. In another embodiment, the etching chemistry mixture has a non-aqueous diluent content of greater than 70%. In another embodiment, the etching chemistry mixture has a non-aqueous diluent content of greater than 75%.

Examples of suitable non-aqueous diluents include, but are not limited to, acids, such as sulfuric acid, oils, such as silicon oil, and organic compounds, such as ethylene glycol, and mixtures thereof. In one embodiment of the present disclosure, the acid is a strong acid having a pH of less than or equal to 1.0.

Regarding temperature, suitable diluents preferably have a higher boiling point than that of phosphoric acid, which is approximately 154° C. for an 85% concentration phosphoric acid. In accordance with one embodiment of the present disclosure, the diluent has a boiling point of greater than the boiling point of 85% concentration phosphoric acid. In another embodiment, the diluent has a boiling point of greater than 300° C. Because of the higher boiling point, chemistries in accordance with embodiments of the present disclosure can be heated to higher temperatures than what is achieved merely by heating phosphoric acid. Such higher temperature help achieve a higher etch rate, as described in greater detail below.

Chemistry mixtures in accordance with the embodiments described above, when etching at 240° C. achieve selectivity for silicon nitride etching compared to silicon oxide etching in a ratio of greater than about 30:1. In accordance with embodiments of the present disclosure, selectivity at these conditions is greater than about 30:1. In accordance with another embodiment, selectivity at these conditions is greater than about 40:1. In accordance with another embodiment, selectivity at these conditions is greater than about 45:1. In accordance with another embodiment, selectivity at these conditions is greater than about 50:1.

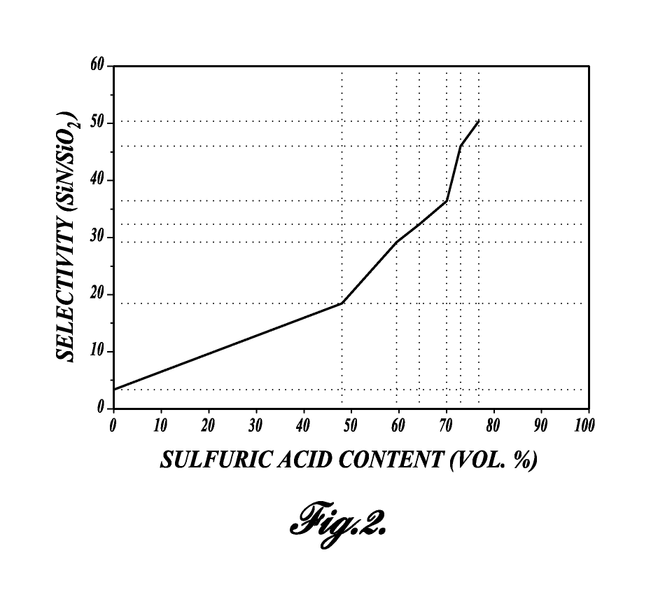

Not wishing to be bound by theory, the inventors believe that there may be other advantageous chemical effects that result in improved silicon nitride etching selectivity when typical phosphoric acid chemistry is mixed with other chemical components, for example, the diluents described above. For example, the inventors believe that strong acids, such as sulfuric acid, have an advantageous effect on selectivity, as seen in the selectivity increase in FIG. 2. In that regard, FIG. 2 is a graphical representation of data for silicon nitride selectivity (as compared to silicon oxide), specifically, the data relates to sulfuric acid content in etching chemistry (balance is phosphoric acid and water) and the increase in selectivity achieved by increasing sulfuric acid content in the etching chemistry.

Other non-acidic, non-aqueous diluents, may include silicon oil, ethylene glycol, or other inert liquids that can be used to dilute phosphoric acid without increasing the water content of the etching chemistry.

The process further includes heating at least one of the workpiece and the chemistry mixture to a process temperature. As described in U.S. patent application Ser. No. 12/837,327, filed Jul. 15, 2010, titled “Systems and Methods for Etching Silicon Nitride” the disclosure of which is hereby expressly incorporated by reference, high temperature heating can be achieved using localized infra-red heating on the workpiece.

Generally described, etching chemistry may be supplied into a workpiece processing chamber, preferably as an aerosol or atomized mist. Using a rotor, the workpiece is rotated to help make infrared radiation and heating more uniform across the surface of the workpiece. After supplying etching chemistry to the workpiece, an infrared lamp is used to rapidly increase the wafer temperature to a processing temperature, typically between 200° C. and 350° C., although other ranges may also be used. The workpiece is maintained at the processing temperature for a specific period of time, for example, 20-100 seconds, 30-80 seconds, or 40-70 seconds. The workpiece is then rapidly cooled using, for example, fluid spray of nitrogen gas and/or de-ionized water onto the workpiece.

It should be appreciated that heating can also be achieved by using typical bath heating techniques of immersing a workpiece in an etching chemistry at a typical bath operating temperature. However, the rates achieved by the lower bath temperatures will be significantly lower than the rates achieved at higher process temperatures, and therefore, may not be feasible considering processing schedule.

### EXAMPLES

### Example 1

### Chemistry Including Phosphoric Acid and Sulfuric Acid

Chemistries 1-7 were used to etch LPCVD silicon nitride wafers and silicon oxide wafers. Compare Chemistry 1 (100% phosphoric acid, having about 15% water content) with Chemistry 7 (20% phosphoric acid, 80% sulfuric acid, having a total of about 6.20% water content). Etch rate decreases with decreasing phosphoric acid content from 212.40 in Chemistry 1 to only 50.24 in Chemistry 7 when the etching chemistry is maintained at the same temperature (240° C.). Etch rate decrease with decreasing phosphoric acid content is graphically represented in FIG. 1.

However, the selectivity ratio of silicon nitride to silicon oxide etch dramatically increases with the addition of sulfuric acid and the decrease in total water content from a selectivity of 3.83 with Chemistry 1 to a selectivity of 50.39 with Chemistry 7. Selectivity increase with increasing sulfuric acid content is graphically represented in FIG. 2.

In the data listed below in Table 1, the phosphoric acid is an 85% concentration solution and the sulfuric acid is a 96% concentration solution. Phosphoric acid and sulfuric acid are listed in grams/ml. Phosphoric acid, sulfuric acid, and water in grams add up to 100.

TABLE 1

| | Chemistry | | | | | |
|---|---|---|---|---|---|---|
| | phos- | | | | | |
| | phoric | sulfuric | | Etch rate at | | |
| | acid | acid | Water | 240° C. | | Selectivity |
| | (g/ml) | (g/ml) | (g) | SiN | SiO2 | (SiN:SiO2) |
| Chem | 85.00/100 | 0 | 15.00 | 212.40 | 55.47 | 3.83 |
| 1 | | | | | | |
| Chem | 42.50/50 | 48/50 | 9.50 | 114.86 | 6.22 | 18.48 |
| 2 | | | | | | |
| Chem | 32.30/38 | 59.52/62 | 8.18 | 97.38 | 3.33 | 29.21 |
| 3 | | | | | | |
| Chem | 28.05/33 | 64.32/67 | 7.63 | 85.73 | 2.65 | 32.35 |
| 4 | | | | | | |
| Chem | 22.95/27 | 70.08/73 | 6.97 | 63.38 | 1.74 | 36.42 |
| 5 | | | | | | |
| Chem | 20.40/24 | 72.96/76 | 6.64 | 57.07 | 1.24 | 46.02 |
| 6 | | | | | | |
| Chem | 17/20 | 76.80/80 | 6.20 | 50.24 | 0.997 | 50.39 |
| 7 | | | | | | |

### Example 2

### Etch as a Function of Temperature

Chemistry 1 (from EXAMPLE 1) was used to etch PECVD and LPCVD silicon nitride wafers and silicon oxide wafers at various process temperatures ranging from 200 to 325° C. Comparative data in FIG. 3 shows etch depth for PECVD- and LPCVD-deposited silicon nitride and silicon oxide over increasing temperature. Silicon nitride etch data is measured on the left in angstroms. Silicon oxide etch data is measured on the right in angstroms.

While illustrative embodiments have been illustrated and described, it will be appreciated that various changes can be made therein without departing from the spirit and scope of the disclosure.

1. A method for etching silicon nitride on a workpiece, the method comprising:
(a) exposing the workpiece to a chemistry mixture including phosphoric acid and a diluent, wherein the chemistry mixture has a water content of less than 10% by volume; and
(b) heating at least one of the workpiece and the chemistry mixture to a process temperature to etch silicon nitride from the workpiece.

2. The method of claim 1, wherein the diluent is a non-aqueous diluent.

3. The method of claim 1, wherein the diluent is selected from the group consisting of sulfuric acid, silicon oil, ethylene glycol, and mixtures thereof.

4. The method of claim 1, wherein the diluent is an acid having a pH of less than about 1.0.

5. The method of claim 1, wherein the diluent has a boiling point higher than that of phosphoric acid.

6. The method of claim 1, wherein the chemistry mixture has a boiling point higher than that of phosphoric acid.

7. The method of claim 1, wherein the water content in the mixture is selected from the group consisting of less than about 10% by volume, less than about 9% by volume, less than about 8% by volume, and less than about 7% by volume.

8. The method of claim 1, wherein the chemistry mixture has a phosphoric acid content selected from the group consisting of less than 30% by volume, in the range of 10% to 30% by volume, and in the range of 10% to 20% by volume.

9. The method of claim 1, wherein the wherein the chemistry mixture has a non-aqueous diluent content of greater than 60% by volume.

10. The method of claim 1, wherein the workpiece is exposed to the chemistry mixture in a range of 20-100 seconds.

11. The method of claim 1, wherein the process temperature is in the range of about 200 to about 350° C.

12. The method of claim 1, wherein the workpiece further includes silicon oxide, and wherein silicon nitride is etched faster than silicon oxide at 240° C. at a selectivity ratio selected from the group consisting of greater than about 30, greater than 40, greater than 45, and greater than 50.

13. A method for etching silicon nitride on a workpiece, the method comprising:
(a) exposing the workpiece to a chemistry mixture including phosphoric acid and a diluent, wherein the chemistry mixture has a non-aqueous diluent content of greater than 60% by volume, a phosphoric acid content in the range of about 10% to about 30% by volume, and a water content of less than 10% by volume; and
(b) heating at least one of the workpiece and the chemistry mixture to a process temperature to etch silicon nitride from the workpiece.

14. An etchant solution, comprising:
(a) a non-aqueous diluent content of greater than 60% by volume;
(b) a phosphoric acid content of less than 30% by volume; and
(c) a water content of less than 10%.

15. The etchant solution of claim 14, wherein the non-aqueous diluent is selected from the group consisting of sulfuric acid, silicon oil, ethylene glycol, and mixtures thereof.

16. The etchant solution of claim 14, wherein the non-aqueous diluent is an acid having a pH of less than about 1.0.

17. The etchant solution of claim 14, wherein the non-aqueous diluent has a boiling point higher than that of phosphoric acid.

18. The etchant solution of claim 14, wherein the etchant solution has a boiling point higher than that of phosphoric acid.

19. The etchant solution of claim 14, wherein the water content in the mixture is selected from the group consisting of less than about 9% by volume, less than about 8% by volume and less than about 7% by volume.

20. The etchant solution of claim 14, wherein the chemistry mixture has a phosphoric acid content selected from the group consisting of in the range of 10% to 30% by volume and in the range of 10% to 20% by volume.
